(19) United States
(12) Patent Application Publication
(10) Pub. No.: US 2025/0008695 A1
(43) Pub. Date: Jan. 2, 2025

(54) THERMAL BRIDGE FOR THERMALLY CONDUCTIVE TRANSPORT OF HEAT

(71) Applicant: Phoenix Contact GmbH & Co. KG, Blomberg (DE)

(72) Inventor: Frank BEST, Bueckeburg (DE)

(21) Appl. No.: 18/709,526

(22) PCT Filed: Nov. 11, 2022
(86) PCT No.: PCT/EP2022/081653

§ 371 Date: May 13, 2024

(30) Foreign Application Priority Data
Nov. 15, 2021 (BE) BE2021/5881

(51) Int. Cl. H05K 7/20

(52) U.S. Cl. CPC H05K 7/20409; H05K 7/20963

(57) ABSTRACT

A thermal bridge for a thermally conductive transport of heat includes: a heat release portion having: a joining surface; a heat release surface spaced from the joining surface; and a first material component of the thermal bridge from the joining surface to the heat release surface. The heat release portion releases heat from the joining surface to the heat release surface in a thermally conductive manner and releases the heat at the heat release surface. The thermal bridge includes a heat absorption section connected to the heat release section at the joining surface in a material-locking manner as a material-locking connection, the heat absorption section including: a heat contact surface moldable by contact pressure; and from the joining surface up to the heat contact surface, a second material component of the thermal bridge built up by additive melt layering, the second material component being different from the first material component.

### CROSS-REFERENCE TO PRIOR APPLICATIONS

This application is a U.S. National Phase application under 35 U.S.C. § 371 of International Application No. PCT/EP2022/081653, filed on Nov. 11, 2022, and claims benefit to Belgian Patent Application No. BE 2021/5881, filed on Nov. 15, 2021. The International Application was published in German on May 19, 2023 as WO/2023/084043 under PCT Article 21 (2).

### FIELD

The invention relates to thermal management, for example of waste heat from an electrical heat source. In particular, a thermal bridge for the thermally conductive transport of heat and a method of manufacturing such a thermal bridge are disclosed.

### BACKGROUND

The efficiency of thermal management is described by the thermal conductivity λₜₕ or the reciprocal thermal resistance Rₜₕ of the thermal bridge. In the thermal path of the thermal bridge, heat is transferred from an electrical component as a heat source (also: hotspot) to a cooler body, which acts as a heat sink and emits the heat to the environment, for example. Multi-component thermal bridges are easier to manufacture and can be flexibly combined with different electrical heat sources and different installation positions of the heat sources.

However, every interface in the heat path increases the thermal resistance of the thermal bridge. Fundamentally, the transport of heat is based on at least one of the three physical effects of thermal conduction, thermal convection and thermal radiation. In particular, thermal contact between two solid surfaces is essential for efficient heat conduction.

Heat conducting materials, also known as thermal interface materials (TIM), offer an improvement in heat conduction at such interfaces compared to direct contact between solid surfaces. While TIM further increases the number of interfaces, the improvement in heat conduction is based on the displacement of air layers between contact points of microscopically rough solid surfaces.

However, with conventional joining of heat sinks and TIM, the joining surfaces may be microscopically contaminated after separate production, support and transportation, for example by an oxide layer, dust or condensation. The joining surfaces may also be contaminated by handling during joining. As a result, the thermal conductivity of a conventional thermal bridge falls short of the conductivity possible due to the TIM used on the joining surface.

### SUMMARY

In an embodiment, the present invention provides a thermal bridge for a thermally conductive transport of heat, comprising: a heat release portion comprising: a joining surface; a heat release surface spaced from the joining surface; and a first material component of the thermal bridge from the joining surface to the heat release surface, wherein the heat release portion is configured to release heat from the joining surface to the heat release surface in a thermally conductive manner and to release the heat at the heat release surface; and a heat absorption section connected to the heat release section at the joining surface in a material-locking manner as a material-locking connection, the heat absorption section comprising: a heat contact surface moldable by contact pressure; and from the joining surface up to the heat contact surface, a second material component of the thermal bridge built up by additive melt layering, the second material component being different from the first material component, wherein the heat absorption section is configured to absorb the heat at the heat contact surface and to transport the heat in a heat-conducting manner via the material-locking connection from the heat absorption section to the heat release portion.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1A schematic cross-sectional view of separately manufactured parts of a two-part thermal bridge according to the state of the art:

FIG. 1B schematic cross-sectional view of separately manufactured parts of a three-part thermal bridge according to the state of the art;

FIG. 2 a schematic cross-sectional view of a two-component thermal bridge according to a first or fifth embodiment:

FIG. 3 a schematic cross-sectional view of a two-component or multi-component thermal bridge according to a second or third embodiment:

FIG. 4 a schematic cross-sectional view of a variant for transporting heat through or along a circuit board, which is applicable in each embodiment;

FIG. 5 a schematic cross-sectional view of a two- or multi-component thermal bridge according to a variant of the third embodiment:

FIG. 6 a schematic cross-sectional view of a two-component thermal bridge according to a fourth embodiment:

FIG. 7 a schematic cross-sectional view of a two-component thermal bridge according to a sixth embodiment:

FIG. 8 a schematic cross-sectional view of a variant of any embodiment comprising a temperature sensor:

FIG. 9 a schematic cross-sectional view of a variant of any embodiment comprising at least one heat pipe; and

FIG. 10 an enlargement of an effective area relative to a cross-sectional area of the heat transport.

### DETAILED DESCRIPTION

In an embodiment, the present invention improves the efficiency of multi-component thermal bridges. An alternative or more specific problem is to maintain the efficiency of the multi-component thermal bridge over a plurality of thermal load cycles.

One aspect relates to a thermal bridge for the thermally conductive transport of heat. The thermal bridge comprises a heat dissipation section (or heat emitting section) and a heat absorption section (or heat-receiving section). The heat dissipation section comprises a joining surface and a heat dissipation surface (or heat emitting surface) spaced from the joining surface. The heat dissipation section comprises a first material component of the thermal bridge from the joining surface to the heat dissipation surface. The heat dissipation section is configured to transport the heat from the joining surface to the heat dissipation surface in a thermally conductive manner and to dissipate it at the heat dissipation surface. Furthermore, the thermal bridge comprises a heat absorption section connected to the heat release section on the joining surface. The heat absorption section comprises a heat contact surface (or thermal contact surface) that can be molded (e.g. plastic or elastic) by contact pressure. From the joining surface to the heat contact surface, the heat absorption section comprises a second material component of the thermal bridge built up using additive melt layering. The second material component is different from the first material component. The heat absorption section is configured to absorb the heat at the heat contact surface and to transport it in a heat-conducting manner from the heat absorption section to the heat release section via the material connection.

Embodiments of the thermal bridge may comprise a thermal resistance at the joining surface that is reduced compared to a conventional thermal bridge due to the higher temperature of the additive fusion layering (for example, compared to a conventional joining at room temperature after separate production of the components) (and/or due to the branching at the joining surface). For example, the material closure of the two material components during additive manufacturing displaces the air at the joining surface better (e.g. more completely or completely), as a material closure is created between the heat release section and the heat absorption section at the time of processing (e.g. during the first fusion layering of the second material component on the first material component).

The same or further embodiments of the thermal bridge may obtain the material bond even with different thermal expansion and contraction rates of the various first and second material components at the joining surface (for example the connection between TIM and heat sink) and/or prevent loosening (also referred to as “pump-out” in technical terms) of the thermal contact due to mechanical stresses due to the higher temperature of the additive melt layering (for example compared to a conventional joining at room temperature of the separately produced components) and/or due to the branching at the joining surface.

The adaptably formable (e.g. adaptably moldable) heat contact surface may be configured to mechanically and thermally contact a (e.g. electrical) heat source of the transported heat. For example, the heat contact surface may wet the entire surface of the heat source due to the contact pressure in order to minimize thermal resistance.

The formable heat contact surface may be elastic or plastic. For example, the plastic heat contact surface may be formable or molded to a surface of the heat source by pressing it once and/or adhering to the surface. Alternatively or additionally, the elastic heat contact surface may be formable or molded to a surface by press-fitting the thermal bridge or by permanently elastic force-locking of the thermal bridge, for example between a housing wall of a housing and a surface of the heat source.

Plasticity and elasticity may also be combined in the second material component, for example by forming plasticity when an elasticity limit is exceeded. Alternatively or additionally, the second material component may be viscoelastic. For example, an initially elastic molding to a surface of the heat source may change to a plastic molding after a predetermined time. This may enable trial molding and/or correction of the position of the heat absorption section on the heat source.

The heat source may be an electrical component or a section of a circuit board. The heat contact surface may, for example, contact the circuit board directly and thus indirectly transport the heat of a component through the circuit board, for example with the aid of metallic conductor tracks as heat conductors. The component may be arranged on a side of the section of the circuit board contacted by the heat contact surface facing away from the heat absorption section or on a side facing the heat absorption section next to the contacted section of the circuit board.

Alternatively or additionally, the heat contact surface may make thermal contact with a side surface of the component that extends (for example, essentially) perpendicular to the circuit board. This means that a thermal path determined by the thermal bridge may extend parallel to the circuit board and/or the component may be contacted laterally.

The melt layering of the second material component may comprise a plastic, viscous, elastic or viscoelastic consistency. Alternatively or additionally, a particle size of the second material component in the melt layering may be smaller than at room temperature and/or a viscosity of the second material component in the melt layering may be smaller than at room temperature. Alternatively or additionally, the melt layering of the second material component may creep into the unevenness or microscopic roughness of the joining surface and fill it, for example instead of air. Alternatively or additionally, the melt layering of the second material component (for example, when processed at a temperature greater than room temperature) may provide greater molecular mobility and/or improved cross-linking than the conventional joining between TIM and heat sink or TIM and heat spreader at room temperature (for example, when the heat sink or heat spreader is conventionally assembled).

As the thermal bridge comprises the heat release section and the heat absorption section with the first or second material component, the thermal bridge may also be referred to as a multi-component thermal bridge.

The heat dissipation section may comprise a heat sink (also known as a heat sink) and/or a heat spreader.

The heat absorption section and/or an intermediate section may be manufactured using thermal interface material (TIM) as the second material component by additive manufacturing (AM). This may achieve on-demand manufacturability. For example, a quantity may be equal to 1 and/or it may be manufactured on a customer-specific basis. Alternatively or additionally, the second material component does not have to be pre-assembled. This may eliminate the need for additional technical development (for example in product development and/or production development).

Alternatively or additionally, the additive manufacturing of the heat absorption section and/or the intermediate section may be testable using TIM during the manufacturing process or as part of the manufacturing process.

Alternatively or additionally, additive manufacturing of the heat absorption section and/or the intermediate section using TIM may improve process reliability and process stability. For example, the TIM may be applied reproducibly. The qualification of prototypes in the development phase may correspond to the qualification of series parts.

An electrical component may generate the absorbed and transported heat as a heat source. The electrical component may be embedded in the second material component of the heat absorption section, for example as an insert component during the additive manufacturing of the heat absorption section.

Heat (also: thermal energy) may comprise thermal energy, for example the energy of a disordered microscopic motion.

Thermally conductive transport, i.e. heat conduction (also: heat diffusion or conduction), comprises the transport of thermal energy. In contrast to thermal convection, thermal conduction may transport heat without a (e.g. macroscopic) flow of matter. In contrast to thermal radiation, heat conduction may transport heat (for example only) in matter and/or without (for example macroscopic) electromagnetic radiation. Heat conduction may transport heat towards a lower temperature in accordance with the second law of thermodynamics, i.e. by generating entropy. No heat energy is lost in the process, i.e. the conservation of energy applies.

Alternatively or additionally, the first and/or second material component of the thermal bridge may comprise a dielectric solid (e.g. an electrical insulator). In the dielectric solid, thermal conduction may (for example only) be transported by lattice vibrations (also: phonons). The energy of the disordered motion of the atoms may be exchanged between neighboring atoms. All electrons may be bound to the atoms and therefore make no contribution to thermal conduction.

Alternatively or additionally, the first and/or second material component of the thermal bridge may comprise an electrically conductive solid (e.g. a metal). Electrons may also transport heat in the electrically conductive solid and thus contribute to thermal conduction.

Fluids, i.e. liquids and gases, may in principle conduct heat. In contrast to convection, no macroscopic flow of matter, such as vortices, forms in the fluid in the case of pure heat conduction. Light atoms or molecules conduct heat better than heavy ones, as they move faster with the same energy content.

Preferably, the first and/or second material component of the thermal bridge does not comprise any fluid (for example, no liquid) so that the joining surface, the heat dissipation surface and/or the heat contact surface comprise a defined or predetermined (for example, plastic or elastic) shape. Alternatively or additionally, the first and/or second material component of the thermal bridge does not comprise any fluids (e.g. no gases), as their thermal conductivity is low, for example due to low shear forces and/or in the case of gases due to their low density.

The thermal bridge may comprise only the first material component and the second material component.

The heat dissipation section and/or the heat absorbing section may each be integrally one-piece.

The material-locking connection may comprise the first material component and the second material component in a transition area between the heat-absorbing section and the heat-releasing section. Alternatively or additionally, the joining area may be larger (for example several times larger) than the heat contact area.

The joining surface may comprise a branching or honeycomb structure of the first material component embedded in the second material component.

The heat bridge, for example the heat dissipation section, may comprise a heat sink and/or a heat distributor.

The heat spreader may also be referred to in technical terms as a heat spreader. The heat spreader may comprise copper as the first material component. The heat sink may comprise aluminum as the first material component. Alternatively or additionally, the heat spreader and the heat sink may be integral-one-piece.

The heat dissipation surface may be larger (for example several times larger) than the heat contact surface and/or than the joining surface.

The heat dissipation section of the thermal bridge may be configured to dissipate the heat diffusively, radiatively or convectively at the heat dissipation surface.

The heat dissipation section, for example the heat distributor, may be configured to dissipate the heat to a heat sink by thermal conduction. Alternatively or additionally, the heat dissipation section or the heat sink may be configured to dissipate the heat to an environment of the heat dissipation surface by thermal radiation and/or thermal convection.

The heat dissipation section (for example as a heat spreader) may be configured to dissipate the heat by heat conduction (i.e. diffusively) to a heat sink. Alternatively or additionally, the heat dissipation section (for example as a heat sink) may be configured to dissipate the heat by thermal radiation (i.e. radiative) and/or thermal convection (i.e. convective) to an environment of the heat dissipation surface.

The first material component may comprise a metal (for example an alloy). Alternatively or additionally, the second material component may comprise a thermally conductive material that is plastic, elastic, viscous or viscoelastic under standard or normal conditions.

The first material component may be metallic (for example, a metallic alloy). The first material component may comprise copper or aluminum.

Alternatively or additionally, the second material component may be electrically insulating.

The standard conditions may comprise 273.15 K≙0° C. and 100.000 kPa=1.000 bar. The standard conditions may comprise 273.15 K≙0° C. and 101.325 kPa=1.01325 bar=1 atm. The thermal interface material may also be referred to as thermal interface material (TIM).

The heat dissipation section, the heat sink and/or the heat distributor may be extruded (e.g. manufactured by extrusion), cast and/or sintered and/or manufactured or reworked by machining and/or manufactured from the first material component using additive melt layering.

The casting may be a die casting or a metal powder injection molding (for example with the steps of debinding and sintering). The sintering may comprise sinter-based additive manufacturing. Alternatively or additionally, the heat dissipation section, the heat sink and/or the heat spreader may be the result of machining or post-machining (e.g. milling), for example from a semi-finished product and/or after extrusion or after casting.

Alternatively or additionally, the heat dissipation section, the heat sink and/or the heat distributor may be additively manufactured. This may achieve on-demand manufacturability. For example, a quantity may be equal to 1 and/or it may be manufactured on a customer-specific basis. Alternatively or additionally, the first material component does not have to be pre-assembled. This may eliminate the need for additional technical development (for example in product development and/or production development).

Alternatively or additionally, the heat-absorbing section may be produced with a material bond to the joining surface of the heat-releasing section using additive melt layering of the second material component or by applying the second material component. The second material component may be applied using a syringe, cartridge or tube.

The heat dissipation surface of the heat dissipation section may be a second joining surface. The thermal bridge may also comprise an intermediate section connected to the heat release section at the second joining surface. The intermediate section may comprise a second heat contact surface that can be molded (e.g. plastic or elastic) by contact pressure. From the second joining surface to the second heat contact surface, the intermediate section may comprise the second material component built up using additive melt layering. The intermediate section may be configured to transport the heat from the second joining surface of the heat release section to the second heat contact surface in a thermally conductive manner via the material connection.

A second width of the intermediate section between the second joining surface and the second heat contact surface may be smaller than a first width of the heat absorption section between the heat receiving surface and the joining surface.

The second heat contact surface may be configured to dissipate the heat to a heat sink connected or connectable to the second heat contact surface.

The heat dissipation section may be additively manufactured from the first material component.

For example, the heat spreader may be additively manufactured (e.g. using additive melt layering) on the (e.g. extruded or additively manufactured) heat sink.

The intermediate section may be additively manufactured on a heat sink. The heat dissipation section may be a heat spreader additively manufactured from the first material component on the intermediate section.

The heat dissipation surface of the heat dissipation section may be a second joining surface. The heat bridge may further comprise connection means configured to press the second joining surface of the heat dissipation section with a heat sink with plastic deformation of the second joining surface to produce a heat-conducting connection.

The plastic deformation of the second joining surface may plastically reduce roughness (e.g. microscopic surface peaks) and/or connect the heat dissipation section to the heat sink with a material bond. This may reduce thermal conduction resistance at the connection produced by plastic deformation. The connecting means may comprise at least one screw connection.

The (first) joining surface and the second joining surface may be opposite sides of the heat release section. Alternatively or additionally, the (first) joining surface and the second joining surface of the heat dissipation section may be adjacent to each other, for example at an edge of the heat dissipation section. Alternatively or additionally, the (first) joining surface and the second joining surface may be perpendicular to each other. As a result, the heat path (i.e. the path of heat transport) may change direction, for example by 90°.

A heat path with a uniform direction is also referred to as uniaxial. A heat path with a plurality of (for example, sequential) changes of direction is also referred to as a multi-axis heat path. Embodiments of the multi-axis heat path may allow the heat contact surface to thermally (and mechanically) contact the heat source on any predetermined side, or a plurality of sides.

A temperature sensor for detecting the temperature or a recess for accommodating the temperature sensor may be incorporated using the additive melt layering in the heat absorption section. Alternatively or additionally, a heat pipe for convective transport of the heat or a recess to accommodate the heat pipe may be incorporated in the heat absorption section using the additive melt layering.

The temperature sensor may comprise a piece of metal (for example, a wire with a temperature-dependent conductivity) that is arranged in the heat absorption section using the additive fusion coating. Alternatively or additionally, a recess (e.g. a channel) for the temperature sensor may be provided in the heat absorption section using the additive fusion layering. The temperature sensor may enable direct temperature measurement in the heat path of the heat transport.

The temperature sensor or recess may be arranged in the heat absorption section to detect the temperature in the second material component and/or at the heat contact surface and/or at a surface of the heat source. Alternatively or additionally, the temperature sensor or the recess may be arranged parallel to the surface of the heat source or parallel to the heat contact surface or perpendicular to the transport of the heat.

The heat pipe may also be referred to as a heat pipe. The heat pipe or the recess for accommodating the heat pipe may be arranged in the heat absorption section for convective transport of the heat in the second material component (which also conducts the heat diffusively). Alternatively or additionally, the heat pipe or recess may be arranged perpendicular to the surface of the heat source or perpendicular to the heat contact surface or parallel to the transport of the heat.

According to a further aspect, a method for additively manufacturing a thermal bridge for thermally conductive transport of heat is provided. The method comprises a step of providing a heat release portion of the thermal bridge comprising a joining surface and a heat release surface spaced from the joining surface, and comprising a first material component of the thermal bridge from the joining surface to the heat release surface. The heat dissipation section is configured to transport the heat from the joining surface to the heat dissipation surface in a thermally conductive manner and to dissipate it at the heat dissipation surface. Furthermore, the method comprises a step of additively manufacturing a heat-absorbing section on the joining surface for materially bonding with the heat-releasing section, wherein the heat-absorbing section comprises a heat contact surface (for example plastic or elastic) that can be molded by contact pressure and a second material component of the heat bridge built up from the joining surface to the heat contact surface using additive melt layering. The second material component is different from the first material component. The heat absorption section is configured to absorb the heat at the heat contact surface and to transport it in a heat-conducting manner from the heat absorption section to the heat release section via the material connection.

The step of providing the heat release section of the thermal bridge may comprise additive manufacturing of the heat release section. the additive manufacturing of the heat absorption section may continue the additive manufacturing of the heat release section using fusion layering on the joining surface.

A temperature of the additive melt layering may be greater than a melting temperature of the second material component. Alternatively or additionally, the second material component may be amorphous and a temperature of the additive melt layering may be greater than a glass transition temperature of the second material component.

This may result in additive melt layering during additive manufacturing. Alternatively or additionally, an unavoidable surface roughness of the joining surface may wet the first material component when the second material component softens and/or the additive melt layering may drive air inclusions out of micropores in the joining surface. For example, convex and concave unevenness of the joining surface or tolerances can be compensated for.

Optionally, the second material component comprises a thixotropic flow property in the liquid or viscous state, which prevents the second material component from leaking during additive manufacturing. In this way, a process-reliably uniform material thickness may be achieved and/or precise additive manufacturing may be made possible.

The second material component may wet the first material component at the joining surface. The second material component may wet the first material component (for example in the case of additive melt layering) on the joining surface. The second material component may be wetting on the joining surface if a contact angle of the second material component (for example in the case of additive melt layering) on the joining surface is greater than 90°. The wetting may be recognizable based on the contact angle on the joining surface even after the additive fusion layering has been completed. In this respect, wetting may also be a structural feature of the thermal bridge.

The second material component may wet the first material component on the joining surface according to a surface topology (for example the roughness or waviness) of the joining surface.

The process may further comprise a step of structuring (e.g. fine structuring) the joining surface. For example, the branching or honeycomb structure may be molded onto the joining surface. A ratio of the actual size of the structured or finely structured joining surface to the size of the projected joining surface may be greater than two. Alternatively or additionally, a ratio of the actual size of the finely structured joining surface to the size of the cross-sectional area perpendicular to the transport of heat may be greater than two.

The joining surface of the first material component may be considered wettable by the second material component (for example in the viscous or liquid state) if a contact angle of less than 90° is formed. Due to the fine structuring (e.g. a rough surface as a joining surface), the (e.g. measured or apparent) contact angle may be reduced for given first and second material components, i.e. the joining surface may become even more wettable.

Fine structuring may comprise sanding or sandblasting.

The ratio between the cosine of the measured or apparent contact angle and the cosine of the contact angle of the second material component on a smooth surface of the first material component may, according to R. N. Wenzel (1936), correspond to the roughness of the joining surface, for example the ratio of the actual size of the finely structured joining surface to the size of the projected joining surface.

A conventional heat contact surface within the thermal path of a multi-part thermal bridge, whose separately manufactured parts are assembled to form the thermal bridge during installation, has air pockets at the joint surfaces. The joint surfaces are therefore thermal weak points in the thermally conductive transport.

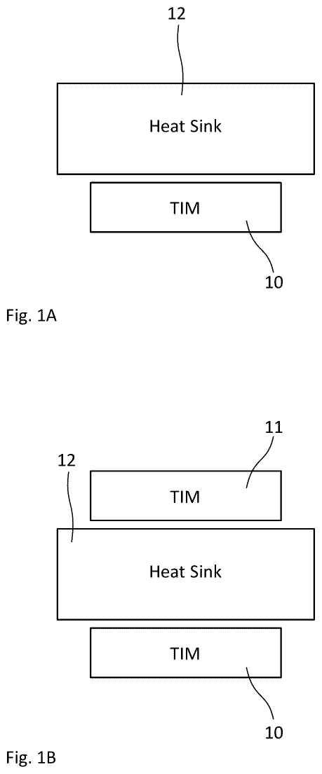

FIG. 1A shows the separately manufactured parts 10 and 12 of a two-part thermal bridge. The TIM 10 may be preformed as a single layer or provided as a paste in a tube.

FIG. 1B shows the separately manufactured (i.e. individual) parts 10, 11 and 12 of a three-part thermal bridge.

In contrast to conventional handling of individual parts (e.g. individual layers at room temperature), additive melt layering may reduce or prevent air inclusions on the joining surface. Alternatively or additionally, the additive fusion coating may create the material bond by wetting the joining surface. Embodiments may thus improve a thermal and/or mechanical connection at the joining points of the thermal bridge.

In contrast to conventional joining, joining using additive melt layering may create the material bond without contact force between the first and second material components at the joining surface. Alternatively or additionally, no contact force is required to reduce or remove trapped air. Embodiments may thus prevent deformation of the thermal bridges.

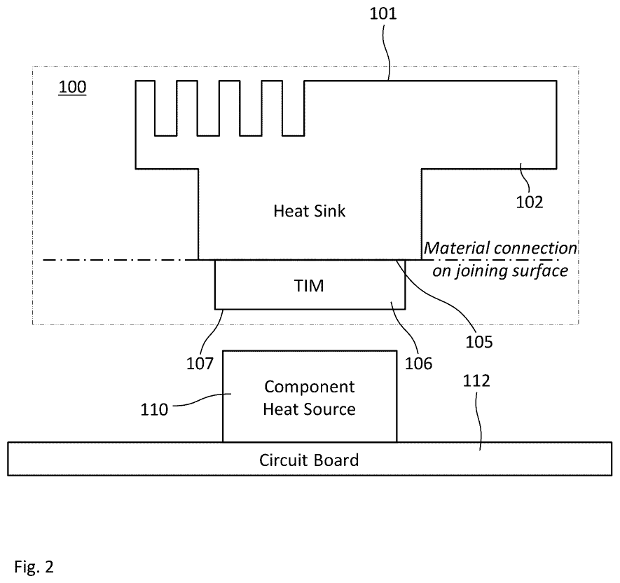

FIG. 2 shows a first embodiment of a thermal bridge, generally designated by reference numeral 100, for the thermally conductive transport of heat from at least one electrical heat source 110, for example on a circuit board 112.

The thermal bridge 100 comprises a heat release section 102 comprising a joining surface 105 and a heat release surface 101 spaced from the joining surface 105. From the joining surface 105 to the heat release surface 101, the heat release section 102 comprises a first material component of the thermal bridge 100. The heat release section 102 is configured to transport the heat from the joining surface 105 to the heat release surface 101 in a thermally conductive manner and to release it at the heat release surface 101.

Furthermore, the thermal bridge 100 comprises a heat-absorbing section 106 connected to the heat-releasing section 102 at the joining surface 105. The heat-absorbing section 106 comprises a heat contact surface 107 that can be formed by contact pressure (for example plastic or elastic) and comprises, from the joining surface 105 to the heat contact surface 107, a second material component of the thermal bridge 100 that is built up using additive melt layering and is different from the first material component. The heat absorption section 106 is configured to absorb the heat at the heat contact surface 107 and to transport it from the heat absorption section 106 to the heat release section 102 in a thermally conductive manner via the material connection.

The first embodiment may be manufactured by at least one of the following process steps. The heat sink 102 may be manufactured by extrusion (for example, extrusion molding), casting (for example, die casting), and/or machining (for example, post-machining of a semi-finished product). The heat absorbing section 106 may be made from a TIM by additive manufacturing.

Thus, the heat absorbing section 106 of the thermal bridge 100 may be integrated into the thermal bridge 100 in the course of additive manufacturing by additive melt layering. For this purpose, the TIM as the second material component of the heat absorbing section 106 is built up on the joining surface 105 of the heat dissipation section 102 produced by extrusion by the additive fusion layering (which may also be referred to as 3D printing). Thus, the joining surface of the heat release portion 102 may serve as the base of the additive melt layering.

The first material component of the heat dissipation section 102 may comprise aluminum. The heat dissipation section 102 may be a heat sink (technically also referred to as a heatsink). The heat sink may integrally and integrally comprise a heat spreader.

While extrusion (i.e., extrusion or extrusion) is mentioned in this and other embodiments as a specific example for manufacturing a part (for example, the heat sink 102 and/or the heat spreader 104), in a variant of each embodiment these parts may also be manufactured by metal casting (for example, sand casting or permanent mold casting), sintering or metal injection molding (technically also referred to as MIM process from English “Metal Injection Molding”).

Optionally, the joining surface 105 may comprise a branching or honeycomb structure of the first material component embedded in the second material component. As a result, the material bond at the joining surface 105 may be positively additional.

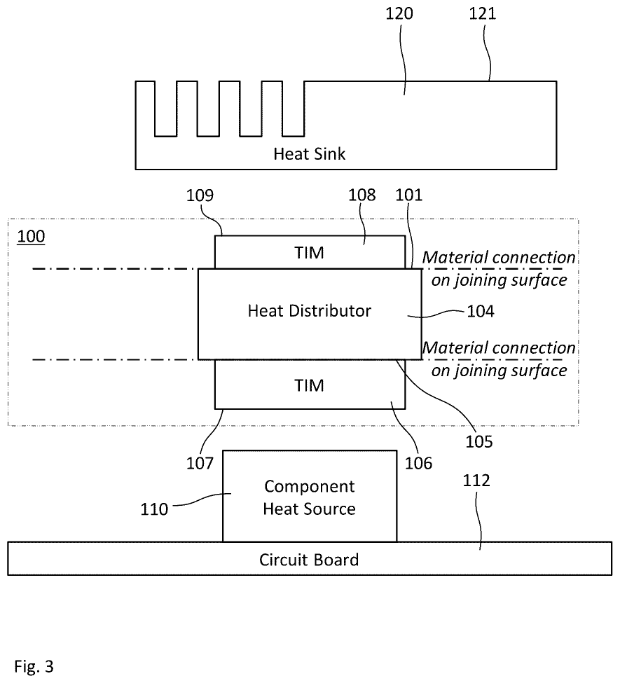

FIG. 3 shows a second embodiment of the thermal bridge 100, which can be realized on its own or in further development of the first embodiment. Features that are provided with matching reference numerals as in FIG. 2 may be identical or interchangeable between the embodiments, for example due to functional equivalence or structural compatibility.

The second embodiment may be produced by at least one of the following process steps. The heat sink 120 may be manufactured by extrusion (for example, extrusion molding), casting (for example, die casting), and/or machining (for example, post-machining of a semi-finished product). The intermediate section 108 may be made from a TIM by additive manufacturing. The heat spreader 104 may be manufactured by extrusion (for example, extrusion molding), casting (for example, die casting), and/or machining (for example, post-machining of a semi-finished product). The heat absorbing section 106 may be made from a TIM by additive manufacturing.

The heat release section may be a heat spreader 104. The heat dissipation surface 101 of the heat dissipation section 104 may be a second joining surface. The heat bridge 100 may further comprise an intermediate portion 108 materially connected to the heat release portion 104 at the second joining surface 101. The intermediate portion 108 may comprise a plastic or elastic second heat contact surface 109 and may comprise the second material component built up using additive melt layering from the second joining surface 101 to the second heat contact surface 109. The intermediate section 108 may be configured to transport the heat from the second joining surface 101 of the heat release section 104 to the second heat contact surface 109 in a thermally conductive manner via the material connection.

The heat distributor 104 may serve as a basis for additive manufacturing by additive melting layers on the (first) joining surface 105 and the second joining surface 101. For this purpose, the heat spreader 104 may be produced by extrusion molding.

According to a third embodiment of the thermal bridge 100, which can be realized by itself or in further development of the first and/or second embodiment, the heat release surface 101 serves as a second joining surface. Features that are provided with corresponding reference numerals as in FIG. 2 or 3 may be identical or interchangeable between the embodiments, for example due to functional equivalence or structural compatibility.

The third embodiment may be manufactured by at least one of the following process steps. The heat sink 120 may be manufactured by extrusion (for example, extrusion molding), casting (for example, die casting), and/or machining (for example, post-machining a semi-finished product) and/or additive manufacturing. The intermediate section 108 may be made from a TIM by additive manufacturing. The heat spreader 104 may be made by additive manufacturing. The heat absorbing section 106 may be made from a TIM by additive manufacturing.

The heat spreader 104 may also be manufactured by additive manufacturing (for example, instead of extrusion). For example, the heat spreader 104 may be manufactured on an auxiliary surface as a basis for additive manufacturing. After completion of the additive manufacturing of the heat distributor 104, it is removed from the auxiliary surface so that the TIM for the heat absorption section 106 or the intermediate section 108 may be built up (for example, successively or simultaneously) on the (first) joining surface 105 and the second joining surface 101 as the basis of the additive fusion layering.

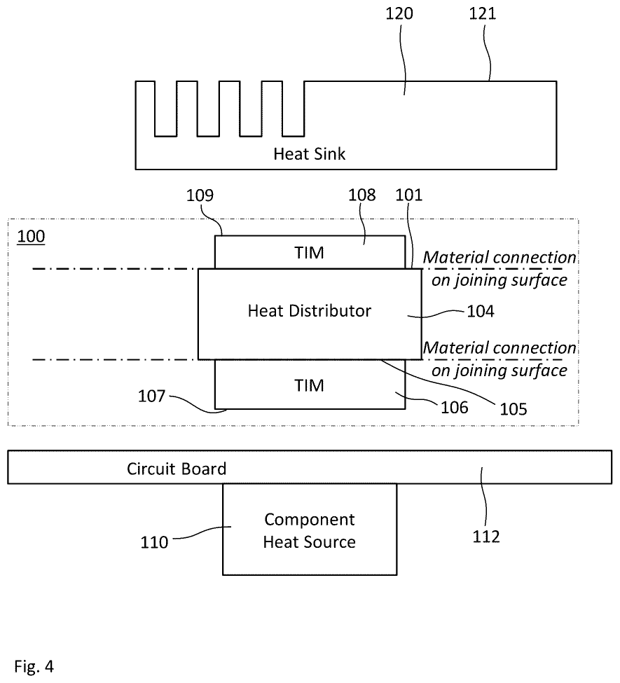

FIG. 4 shows a variant of each embodiment in which the heat contact surface 107 thermally contacts the circuit board 112.

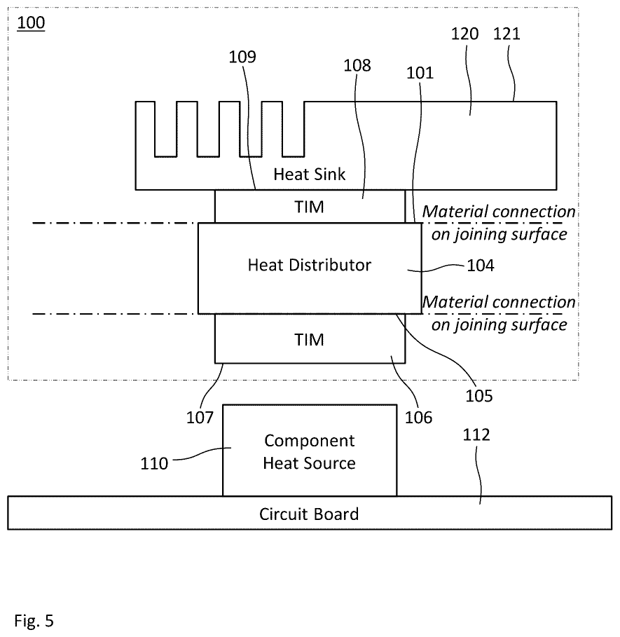

FIG. 5 shows a variant of the third embodiment of the thermal bridge 100, which can be realized on its own or in further development of the first and/or second embodiment. Features that are provided with corresponding reference numerals as in FIGS. 2 to 4 may be identical or interchangeable between the embodiments, for example due to functional equivalence or structural compatibility.

The variant of the third embodiment may be produced by at least one of the following process steps. The heat sink 120 may be manufactured by extrusion (for example, extrusion molding), casting (for example, die casting), and/or machining (for example, post-machining of a semi-finished product). The intermediate section 108 may be made from a TIM by additive manufacturing. The heat spreader 104 may be made by additive manufacturing. The heat absorbing section 106 may be made from a TIM by additive manufacturing.

In a manufacturing step, the intermediate section 108 is additively manufactured on a heat sink 120 (for example manufactured by extrusion or additive manufacturing) by building up the TIM as the second material component by additive melt layering on a surface of the heat sink 120 (which thus corresponds to the heat contact surface 109 of the intermediate section 108). In a further manufacturing step, the heat dissipation section 104 is a heat spreader additively manufactured from the first material component on a surface of the intermediate section 108 (which thus corresponds to the heat dissipation surface 101 of the heat dissipation section 104). In a further manufacturing step, the heat absorption section 106 is built up on the joining surface 105 by additive melt layering.

This sequence of successive additive fusion layers consisting of alternating first and second material components may also be referred to as additive sandwich production.

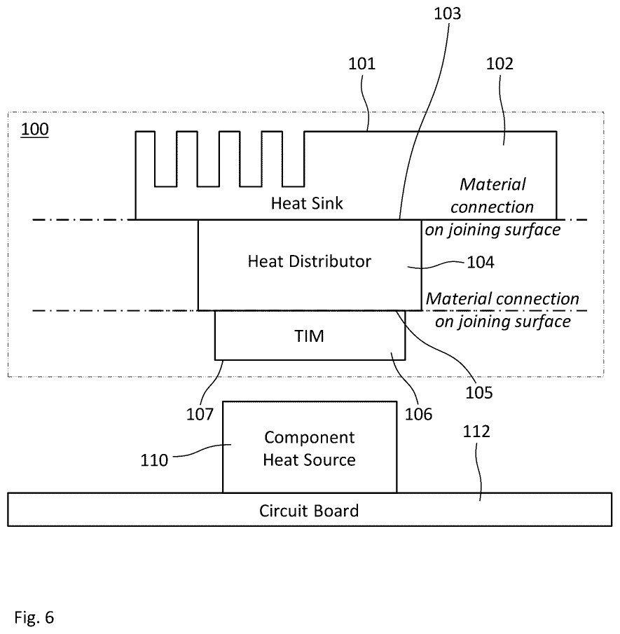

FIG. 6 shows a fourth embodiment of the thermal bridge 100, which can be realized on its own or in further development of the first, second and/or third embodiment. Features provided with corresponding reference numerals as in FIGS. 2 to 5 may be the same or interchangeable between the embodiments, for example due to functional equivalence or structural compatibility.

The fourth embodiment may be produced by at least one of the following process steps. The heat sink 120 may be manufactured by extrusion (for example, extrusion molding), casting (for example, die casting), and/or machining (for example, post-machining of a semi-finished product). The heat spreader 104 may be made by additive manufacturing. The heat absorbing section 106 may be made from a TIM by additive manufacturing.

The heat dissipation section comprises a heat sink 102 (which is manufactured, for example, by extrusion molding and/or additive melt layering of the first material component) and a heat spreader 104 which is additively manufactured on a joining surface 103 between the heat sink 102 and the heat spreader 104, for example, by additive melt layering of the first material component.

According to a fifth embodiment of the thermal bridge 100, for example according to FIG. 2, heat sinks and/or heat distributors are produced by additive manufacturing. The fifth embodiment of the thermal bridge 100 may be realized by itself or in further development of the first, second, third and/or fourth embodiment.

The fifth embodiment may be manufactured by at least one of the following process steps. The heat sink 102 may be manufactured by additive manufacturing. The heat absorbing section 106 may be manufactured from a TIM by additive manufacturing, for example originating from the joining surface 105.

The heat dissipation section comprises a heat sink 102. Preferably, the heat dissipation section comprises (towards the heat absorption section 106) an integral-one-piece heat spreader. In an additive manufacturing of the heat dissipation section 102, the heat sink and the heat spreader may be integrally integrally formed from the first material component.

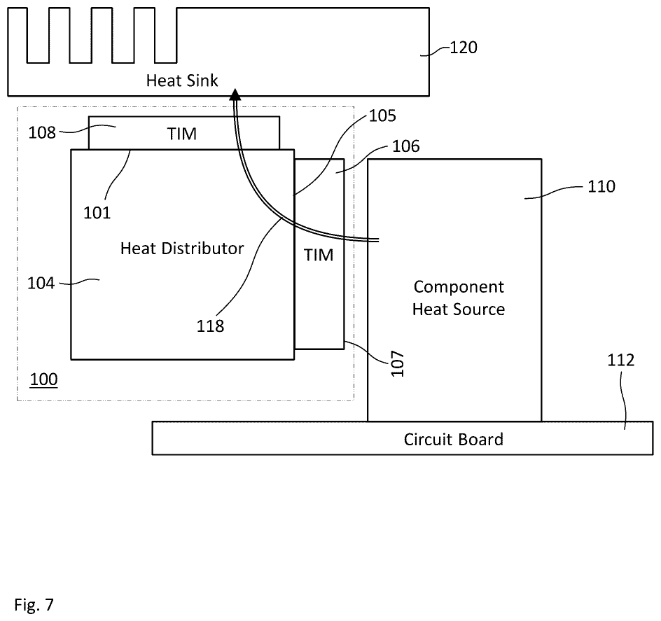

FIG. 7 shows a sixth embodiment of the thermal bridge 100, which can be realized on its own or in further development of the first to fifth embodiments. Features that are provided with corresponding reference numerals as in FIGS. 2 to 6 may be identical or interchangeable between the embodiments, for example due to functional equivalence or structural compatibility.

The (first) joining surface 105 between the heat distributor 104 as heat dissipation section and the heat absorption section 106 is arranged on a first side of the heat distributor 104.

The heat dissipation surface 101 of the heat dissipation section 104 is a second joining surface on a second side of the heat distributor 104. The thermal bridge 100 comprises an intermediate section 108 connected to the heat dissipation section 104 at the second joining surface 101.

The intermediate section 108 may comprise a plastic or elastic second heat contact surface 109 and/or comprise the second material component built up using additive melt layering from the second joining surface 101 to the second heat contact surface 109. The intermediate section 108 may be configured to transport the heat from the second joining surface 101 of the heat release section 104 to the second heat contact surface 109 in a thermally conductive manner via the material connection.

The first side and the second side, i.e., the first joining surface 105 and the second joining surface 101, may be adjacent to each other, for example, in contrast to the third embodiment in which the first joining surface 105 and the second joining surface 101 are opposite sides of the heat release portion 104. As a result, a direction of a heat path 118 may be changed (i.e., directed) along the heat path 118, for example by 90°. This is advantageous, for example, for a lateral heat tapping shown in FIG. 7, i.e. when the heat contact surface 107 contacts the heat source 110 laterally (i.e. parallel to the circuit board 112) and is to be dissipated perpendicular to the circuit board 112.

The sixth embodiment may be manufactured by at least one of the following process steps. The heat sink 120 may be manufactured by extrusion (for example, extrusion molding), casting (for example, die casting), and/or machining (for example, post-machining a semi-finished product) and/or additive manufacturing. The heat spreader 104 may be manufactured by extrusion (for example, extrusion molding), casting (for example, die casting), and/or machining (for example, post-machining of a semi-finished product), and/or additive manufacturing. The heat absorbing section 106 may be made from a TIM by additive manufacturing. The intermediate section 108 may be made from a TIM by additive manufacturing.

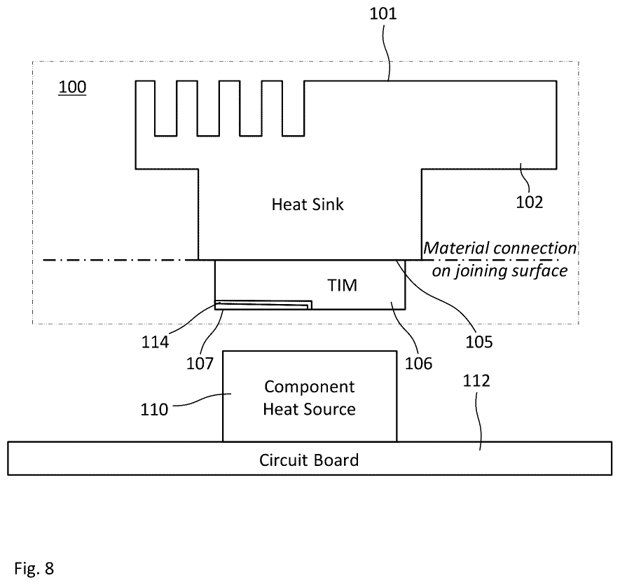

FIG. 8 schematically shows a temperature sensor 114 (i.e. a temperature sensor) or a recess (for example a channel) for receiving the temperature sensor 114, which can be realized in a variant of each embodiment of the thermal bridge 100. An evaluation electronics of the temperature sensor 114 may be connected to the temperature sensor 114 in an electrical conductive manner outside the thermal bridge 100, for example via measuring leads through the channel.

The temperature sensor 114 may be produced in the course of the additive melt layering together with the heat receiving portion 106, for example as an electrical conductive (for example metallic) wire which is introduced into the channel by a linear movement of a print head.

Alternatively or additionally, the temperature sensor 114 may be arranged in a recess in the heat sink 102 or directly on the heat source 110.

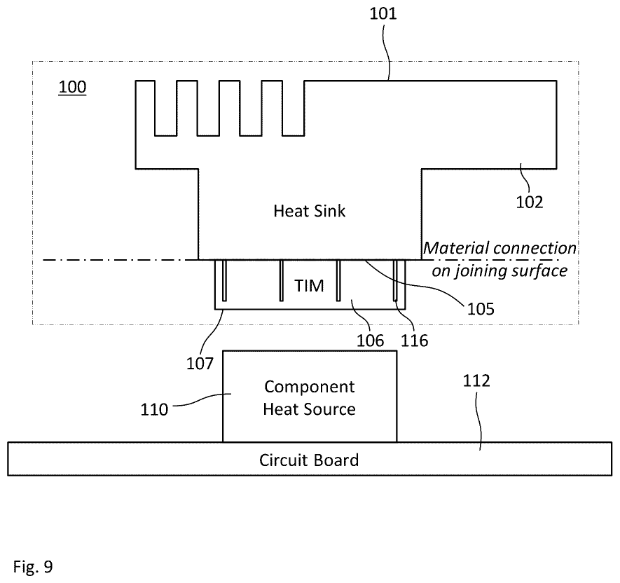

FIG. 9 schematically shows one or a plurality of heat pipes 116 (in technical terms also: heat pipe) or one or a plurality of recesses (for example channels) in each case for receiving the heat pipe 116, which can be realized in a variant of each embodiment of the thermal bridge 100.

The heat pipe 116 or corresponding channel may be produced during the additive melt layering process together with the heat absorption section 106, for example as a metallic tube in which a refrigerant is enclosed.

The heat pipe or pipes 116 preferably extend parallel to the transport of the heat. Alternatively or additionally, the heat pipe or pipes 116 are flush with the joining surface 105.

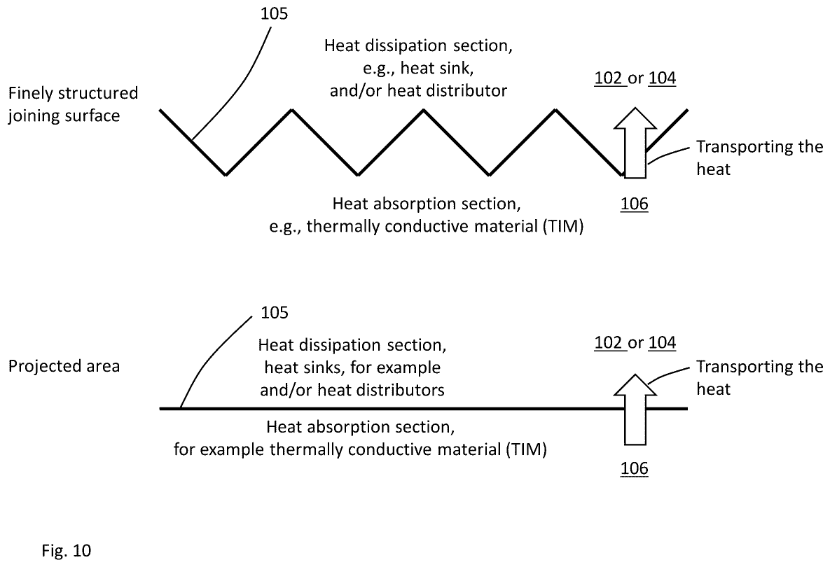

FIG. 10 schematically shows the difference in the interface content (e.g. an effective area) of a finely structured joining surface 105 and a surface projected perpendicular to the transport of the heat, i.e. a flat cross-sectional area perpendicular to the transport (i.e. the direction of transport) of the heat.

The triangular structure shown in FIG. 10 is a schematic example of fine structuring. For example, the finely structured joining surface 105 may have elevations and/or depressions that increase its effective area per cross-sectional area. For example, a ratio of the actual size of the finely structured joining surface 105 to the size of the cross-sectional area perpendicular to the transport of heat may be greater than two.

The fine structuring may increase an effective area between the first and second material components. The fine structuring may be produced in the course of additive manufacturing of the heat absorbing section 106 and/or the heat releasing section 102 or 104.

While with reference to FIG. 10 and the boundary layer of the (first) joining surface 105 between the heat absorption section 106 and heat dissipation section 102 or 104 a fine structuring is disclosed, the second joining surface 101 between heat distributor 104 and intermediate section 108 may also be finely structured if necessary.

In any embodiment, said additive manufacturing may comprise additive melt layering.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

Thermal bridge 100
Heat dissipation area of the heat dissipation section 101
Heat dissipation section as heat sink, also known as heatsink 102
Optional joining surface between heat sink and heat distributor 103
Heat dissipation section as heat distributor, also known as heat spreader 104
Joining surface between heat absorption section and heat dissipation section 105
Heat absorption section made of heat conducting material, also known as Thermal Interface Material (TIM) 106
Formable heat contact surface of the heat absorption section 107
Intermediate section 108
Formable heat contact surface of the intermediate section 109
Electrical heat source, e.g. component 110
Circuit board 112
Temperature sensor 114
Heat pipe 116
Heat path 118
Separate heat sink 120
Heat dissipation surface of the separate heat sink 121

1. A thermal bridge for a thermally conductive transport of heat, comprising:
a heat release portion comprising:
a joining surface;
a heat release surface spaced from the joining surface; and
a first material component of the thermal bridge from the joining surface to the heat release surface,
wherein the heat release portion is configured to release heat from the joining surface to the heat release surface in a thermally conductive manner and to release it the heat at the heat release surface; and
a heat absorption section connected to the heat release section; at the joining surface in a material-locking manner as a material-locking connection, the heat absorption section comprising:
a heat contact surface moldable by contact pressure; and
from the joining surface up to the heat contact surface, a second material component of the thermal bridge built up by additive melt layering, the second material component being different from the first material component,
wherein the heat absorption section is configured to absorb the heat at the heat contact surface and to transport the heat in a heat-conducting manner via the material-locking connection from the heat absorption section to the heat release portion.

2. The thermal bridge of claim 1, wherein the joining surface comprises a branching or honeycomb structure of the first material component embedded in the second material component.

3. The thermal bridge of claim 1, wherein the thermal bridge comprises a heat sink and/or a heat spreader.

4. The thermal bridge of claim 1, wherein the heat dissipation section is configured to emit the heat to a heat sink by heat conduction, or
wherein the heat dissipation section or the heat sink is configured to emit the heat to an environment of the heat dissipation surface by heat radiation and/or heat convection.

5. The thermal bridge of claim 1, wherein the first material component comprises a metal, and/or
wherein the second material component comprises a thermal conductive material that is plastic, elastic, viscous or viscoelastic under standard conditions or normal conditions.

6. The thermal bridge of claim 1, wherein the heat release section is extruded, cast, and/or sintered, and/or is produced or post-processed by machining, and/or
wherein the heat release section is produced from the first material component by additive melt layering.

7. The thermal bridge of claim 1, wherein the heat absorbing section is fabricated in a materially bonded manner on the joining surface of the heat releasing section by additive melt layering of the second material component or by applying the second material component.

8. The thermal bridge of claim 1, wherein an electrical component generating absorbed and transported heat is embedded as a heat source in the second material component of the heat absorbing section.

9. The thermal bridge of claim 1, wherein the heat release surface of the heat release section is comprises a second joining surface, and
wherein the thermal bridge further comprises:
an intermediate section connected to the second joining surface to the heat release section in a material-locking manner as a further material-locking connection; and
a second heat contact surface moldable by contact pressure, the second heat contact surface comprising the second material component built up by additive melt layering from the second joining surface to the second heat contact surface,
wherein the intermediate section is configured to transport heat from the second joining surface of the heat release section to the second heat contact surface in a thermally conductive manner via the further material-locking connection.

10. The thermal bridge of claim 1, wherein the heat release surface of the heat release portion comprises a second joining surface, and
wherein the thermal bridge further comprises:
connection means configured to press the second joining surface of the heat dissipation section with plastic deformation of the second joining surface with a heat sink to produce a heat-conducting connection.

11. The thermal bridge of claim 1, wherein the joining surface and the second joining surface comprise opposite sides or adjacent sides of the heat release section.

12. The thermal bridge of claim 1, wherein a temperature sensor configured to detect a temperature or a recess configured to receive the temperature sensor is introduced in the heat absorption section by the additive melt layering, and/or
wherein a heat pipe configured for convective transport of the heat or a recess configured to receive the heat pipe is provided in the heat absorption section by the additive melt layering.

13. A method of additively manufacturing a thermal bridge for a thermally conductive transport of heat, the method comprising:
providing a heat release portion of the thermal bridge comprising:
a joining surface;
a heat release surface spaced from the joining surface; and
a first material component of the thermal bridge from the joining surface to the heat release surface,
wherein the heat release portion is configured to release heat from the joining surface to the heat release surface in a thermally conductive manner and to release the heat at the heat release surface; and
additively producing a heat absorption section on the joining surface for materially bonded connection with the heat release portion as a material-locking connection, the heat absorption section comprising:
a heat contact surface moldable by contact pressure; and
from the joining surface up to the heat contact surface, a second material component of the thermal bridge built up by additive melt layering, the second material component being different from the first material component,
wherein the heat absorption section is configured to absorb the heat at the heat contact surface and to transport the heat in a heat-conducting manner via the material-locking connection from the heat absorption section to the heat release portion.

14. The method of claim 13, wherein providing the heat releasing portion of the thermal bridge comprises additively manufacturing the heat releasing portion, and
wherein the additively manufacturing of the heat receiving portion continues the additively manufacturing of the heat releasing portion by fusion layering at the joining surface.

15. The method of claim 13, wherein a temperature of the additive melt layering is greater than a melting temperature of the second material component, and/or
wherein the second material component is amorphous and a temperature of the additive melt layering is greater than a glass transition temperature of the second material component.

16. The method of claim 13, wherein the second material component wets the first material component at the joining surface.

17. The method of claim 13, further comprising:
finely structuring the joining surface or the second joining surface as a finely structured joining surface,
wherein a ratio of an actual size of the finely structured joining surface to a size of the cross-sectional area perpendicular to a transport of the heat is greater than two.

18. The thermal bridge of claim 3, wherein the heat dissipation section comprises the heat sink and/or the heat spreader.

19. The thermal bridge of claim 9, wherein the intermediate portion is fabricated on a heat sink by additive fusion layering, and
wherein the heat dissipation portion comprises a heat spreader additively manufactured from the first material component on the intermediate portion.
